(19) United States
(12) Patent Application Publication
(10) Pub. No.: US 2007/0235754 A1
(43) Pub. Date: Oct. 11, 2007

(54) Electronic switch circuit

(75) Inventor: Hiroshi Yamamoto, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 11/783,082

(22) Filed: Apr. 5, 2007

(30) Foreign Application Priority Data
Apr. 6, 2006 (JP) 2006-105356

(51) Int. Cl. H01L 29/74

(52) U.S. Cl. 257/124

(57) ABSTRACT

Electronic switch device having a smaller number of component parts. Resistor R1 is connected between gate and source of a PchTr P1 and resistor R2 is connected between gate of the PchTr P1 and one end of pushbutton switch SW. Resistor R3 is connected between drain of the PchTr P1 and gate of NchTr N1, and resistor R4 is connected between gate and source of the NchTr N1. The NchTr N1 has source connected to one end of DC power supply 11 and to one end of load 12, while having drain connected to the gate of the PchTr P1. The PchTr P1 has source connected to the other end of the DC power supply 11, while having drain connected to the other end of the load 12. Capacitor C has one end connected to one end of pushbutton switch SW, while having the other end connected to one end of the DC power supply. The pushbutton switch SW has the other end connected to the gate of the NchTr N1. The PchTr P1 is alternately repeatedly rendered conductive and non-conductive for each opening/closing operation.

### FIELD OF THE INVENTION

This invention relates to an electronic switch circuit. More particularly, this invention relates to a latch type electronic switch circuit alternately repeatedly rendered conductive and non-conductive each time it is opened/closed.

### BACKGROUND OF THE INVENTION

In a variety of electronic equipment, a latch type switch circuit, turning an electronic device on or off on pushbutton operation, is widely used. FIG. 3 depicts a circuit diagram of a conventional electronic switch circuit constructed using a toggle flipflop circuit. Referring to FIG. 3, an electronic switch circuit 100 includes resistors R11, R12 and R13, a capacitor C11, a P-channel MOSFET P10, inverter circuits INV1, INV2, AND circuits AND1, AND2, an OR circuit OR1 and a pushbutton switch SW.

Referring to FIG. 3, an output of the OR circuit OR1 is set, on power up, to a high potential side of a DC power supply 11, by capacitance across the source and the gate of the P-channel MOSFET P10. Hence, one of the inputs of the AND circuit AND2, connected to the output of the OR circuit OR1, becomes HIGH in level. On the other hand, the input of the inverter circuit INV2 is grounded via resistor R12 and is LOW in level, so that the output of the inverter circuit INV2 becomes HIGH in level and hence the other input of the AND circuit AND2 becomes HIGH in level. Consequently, the output of the AND circuit AND2 is also HIGH in level and hence the output of the OR circuit OR1 is at HIGH level in stability. On the other hand, the output of the inverter circuit INV1, connected to the output of the OR circuit OR1, that is, one of the inputs of the AND circuit AND1, is LOW in level. The other input of the AND circuit AND1 is LOW in level by the resistor R12.

If now the pushbutton switch SW is pressed, the electrical charges in the capacitor C11, accumulated through the resistor R11, are discharged via resistor R12, so that a pulse of the electrical voltage is applied to the resistor R12. With the rising of this pulse of the electrical voltage, the output of the inverter circuit INV2 becomes LOW in level. An output of the AND circuit AND2, constituting a toggle flipflop circuit, becomes LOW in level, and hence the output of the OR circuit OR1 is turned to the LOW level, thus driving the P-channel MOSFET P10 to an on-state. The flipflop circuit keeps this state even when the pushbutton switch SW is released.

If the pushbutton switch SW is once released and again pressed, the electrical charges accumulated in the interim in the capacitor C11 are again discharged to the resistor R12, so that a pulse of the electrical voltage is again supplied to the resistor R12. By this pulse of the electrical voltage, one of the inputs of the AND circuit AND1 becomes HIGH in level. Since the output of the inverter circuit INV1, connected to the other input of the AND circuit AND1, is HIGH in level, the output of the AND circuit AND1, constituting the toggle flipflop, becomes HIGH in level, so that the output of the OR circuit OR1 is turned to the HIGH level. Hence, the P-channel MOSFET P10 is turned off and maintained in this state even after the pushbutton switch SW is released. This sequence of operations is repeated. That is, the load 12 is controlled in its on/or off state, by repetition of the above operations, each time the pushbutton switch SW is pressed and released.

As a related technique, a DC consent which is not subjected to arcing when inserting and extracting a plug is disclosed in Patent Document 1.

### [Patent Document 1]

JP Patent Kokai Publication No. JP-P2005-294080A

### SUMMARY OF THE DISCLOSURE

The entire disclosure of the Patent Document 1 is herein incorporated by reference thereto. In the following analytical considerations are given by the present invention.

The circuit shown in FIG. 3 suffers from the problem that it uses larger numbers of component parts, so that, if the circuit is used frequently for electronic equipment, the production cost tends to be raised.

According to a first aspect of the present invention, there is provided an electronic switch circuit comprising: a switch device, a capacitive device, a field effect transistor of a first conductivity type and a field effect transistor of a second conductivity type. The capacitive device is alternately repeatedly charged and discharged responsive to a timing at which the switch device is opened/closed. The field effect transistor of the first conductivity type is controlled by a potential of the capacitive device so as to be alternately rendered conductive and non-conductive. The field effect transistor of the second conductivity type short-circuits an electrical path between a power supply and a load responsive to a conductive state of the field effect transistor of the first conductivity type. The field effect transistor of the second conductivity type also opens the electrical path responsive to a non-conductive state of the field effect transistor of the first conductivity type. The field effect transistor of the second conductivity type constitutes a latch circuit together with the field effect transistor of the first conductivity type.

The electronic switch circuit may further comprise: a first resistor connected between the gate and the source of the field effect transistor of the second conductivity type; a second resistor connected between the gate of the field effect transistor of the second conductivity type and one end of the switch device; a third resistor connected between the drain of the field effect transistor of the second conductivity type and the gate of the field effect transistor of the first conductivity type; and a fourth resistor connected between the gate and the source of the field effect transistor of the first conductivity type; wherein the field effect transistor of the first conductivity type has a source connected to one end of the DC power supply and to one end of the load and having a drain connected to the gate of the field effect transistor of the second conductivity type; the field effect transistor of the second conductivity type has a source connected to the other end of the DC power supply and having a drain connected to the other end of the load; the capacitive device has one end connected to the one end of the switch device and having the other end connected to one end of the DC power supply; and the switch device has the other end connected to the gate of the field effect transistor of the first conductivity type.

It is preferred that with a resistance value R1 of the first resistor, a resistance value R2 of the second resistor, a resistance value R3 of the third resistor, a resistance value R4 of the fourth resistor, the gate cut-off voltage Vn of the field effect transistor of the first conductivity type, the gate cut-off voltage Vp of the field effect transistor of the second conductivity type, the gate voltage Vng of the field effect transistor of the first conductivity type for which the field effect transistor of the first conductivity type is turned on, and with a voltage Vdc of the DC power supply, the following relationships:

Vdc×R1/(R1+R2)<Vp

Vdc×R4/(R1+R2+R4)<Vn

Vdc×r0/(R3+r0)>Vng

are met, where

r0=R2×R4/(R2+R4).

Further, it s preferred that the switch device comprises a pushbutton switch.

The meritorious effects of the present invention are summarized as follows.

According to the present invention, it is possible to reduce the number of component parts of the switch circuit to lower its production cost.

### BRIEF DESCRIPTION OF THE DRAWINGS

FIG. 1 is a circuit diagram of an electronic switch circuit according to an embodiment of the present invention.

FIG. 2 is a timing chart showing the operation of an electronic switch circuit of the embodiment of the present invention.

FIG. 3 is a circuit diagram of a conventional electronic switch circuit.

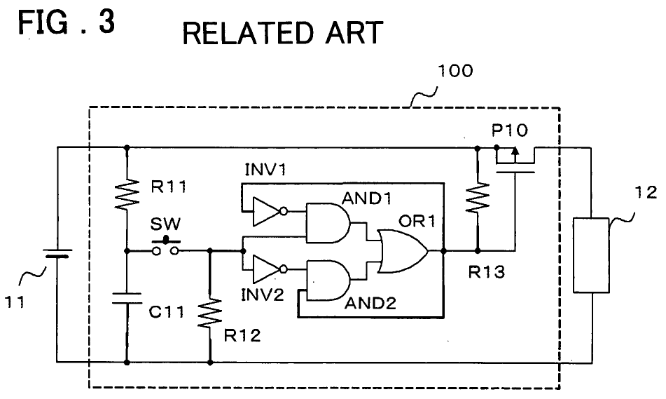

### PREFERRED MODES OF THE DISCLOSURE

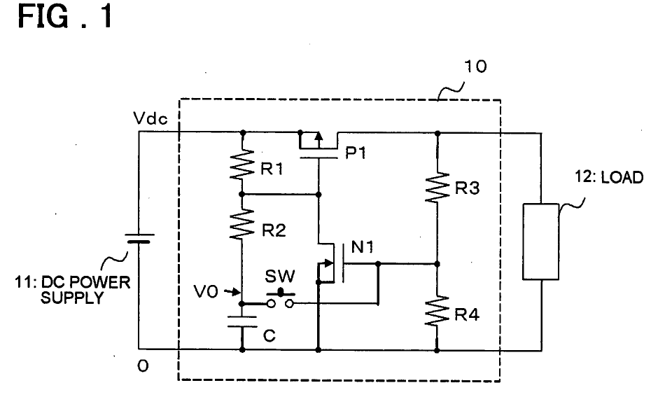

FIG. 1 depicts a circuit diagram of an electronic switch circuit according to an example of the present invention. In FIG. 1, an electronic switch circuit 10 includes resistors R1 to R4, a capacitor C1, a P-channel MOSFET P1, abbreviated herein to PchTr P1, an N-channel MOSFET N1, abbreviated herein to NchTr N1, and a pushbutton switch SW. The resistor R1 is connected between the gate and the source of the PchTr P1. The resistor R2 is connected between the gate of the PchTr P1 and one end of the pushbutton switch SW. The resistor R3 is connected between the drain of the PchTr P1 and the gate of the NchTr N1. The resistor R4 is connected between the gate and the source of the NchTr N1. This NchTr N1 has its source connected to one end of a DC power supply 11 and to one end (zero voltage side) of a load 12, while having a drain connected to the gate of the PchTr P1. The PchTr P1 has a source connected to the other end (voltage Vdc side) of the DC power supply 11, while having a drain connected to the other end of the load 12. The capacitor C1 has its one end connected to one end of the pushbutton switch SW, while having its other end connected to one end of the DC power supply 11. The pushbutton switch SW has its other end connected to the gate of the NchTr N1. The electronic switch circuit 10 can be formed in a semiconductor device except the pushbutton switch SW. In that case, the pushbutton switch SW, the DC power supply and the load may be externally coupled to the electronic switch circuit 10 in the semiconductor device.

The resistors R1 and R2 are to satisfy the following inequality:

Vdc×R1/(R1+R2)<Vp (1)

where Vp is a gate cut-off voltage of the PchTr P1 and Vdc is a voltage of the DC power supply 11. The resistors R1 and R2 are set to high resistance values to reduce power consumption of the entire circuit.

It is noted that the PchTr P1 is such a transistor that is turned on by applying the voltage Vdc of the DC power supply 11 across its source and gate.

The resistors R1, R2 and R4 are to satisfy the following inequality:

Vdc×R4/(R1+R2+R4)<Vn (2)

where Vn is the gate cutoff voltage of the NchTr N1. R4 is set to a high resistance value, as are the resistors R1 and R2.

The resistors R2, R3 and R4 are to satisfy the following inequality:

Vdc×r0/(R3+r0)>Vng (3)

where Vng is the gate voltage of the NchTr N1 for which the transistor is turned on, and r0=R2×R4/(R2+R4). The resistor R3 is similarly set to a high resistance value.

Meanwhile, the capacitance of the capacitor C is set to a value sufficiently higher than the capacitance present across the gate and the source of the NchTr N1.

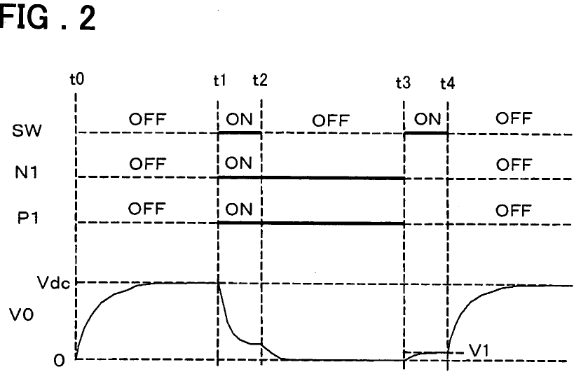

The operation of the electronic switch circuit 10, constituted as described above, will now be described. FIG. 2 depicts a timing chart showing the operation of the electronic switch circuit 10, where V0 denotes the voltage of the capacitor C.

### (1) The State in Which the PchTr P1 is Off Directly After the Power Supply is Turned on

At a timing to when the DC power supply is turned on, the charging voltage V0 of the capacitor C is zero. Hence, a voltage equal to division of the power supply voltage Vdc with the resistors R1 and R2 is applied to the gate of the PchTr P1. This applied voltage is smaller than the gate cutoff voltage Vp of the PchTr P1, as shown in the equation (1), and hence the PchTr P1 is maintained in the OFF state. The capacitor C is charged through the resistors R1 and R2 to the voltage Vdc of the DC power supply.

### (2) On-Operation of the PchTr P1 by Initial Actuation of the Pushbutton Switch SW

When the pushbutton switch SW is closed at a timing t1, the charging voltage V0 of the capacitor C is applied between the gate and the source of the NchTr N1. Since this applied voltage is higher than the gate cut-off voltage Vn, the NchTr N1 is turned on, so that the transistor acts as a low resistance. Hence, a driving voltage which is necessary and sufficient to turn on the PchTr P1 is supplied to its gate, so that the PchTr P1 is turned on to drive the load 12. There is also applied a voltage corresponding to division of the power supply voltage Vdc by the resistors R3 and R4 to the gate of the NchTr N1.

When the pushbutton switch SW is closed, the resistors R4, R2 and the capacitor C are connected in parallel with the gate of the NchTr N1. Since the voltage at a voltage dividing point (charging voltage V0 of the capacitor C) is set so as to be larger than Vng, as shown in the equation (3), the NchTr N1 keeps its on-state.

When the pushbutton switch SW is then opened, at a timing t2, the electrical charges of the capacitor C are discharged through the resistor R2 and the NchTr N1 to fall to substantially a zero value. The on-state of the NchTr N1 and that of the PchTr P1 keep on to be maintained.

### (3) Off-Operation of the PchTr P1 by Second Actuation of the Pushbutton Switch SW

When the pushbutton switch SW is again closed at a timing t3, the gate of the NchTr N1 is connected to the capacitor C which is in the zero capacitance state. Hence, the gate voltage of the NchTr N1 is lowered precipitously. Thus, the NchTr N1 is turned off, so that the PchTr P1 is turned off and the voltage ceases to be supplied to the load 12.

Directly after closure of the pushbutton switch SW, the capacitor C is re-charged through resistor R3. However, since the NchTr N1 is off, charging of the capacitor C is now from the series circuit of the resistors R1 and R2. Even if the pushbutton switch SW keeps on to be pressed, that is, closed, the voltage V0 of the capacitor C is maintained at a voltage V1 corresponding to Vdc divided by the resistors R1, R2 and R4 (=Vdc×R4/(R1+R2+R4)). That is, the gate voltage of the NchTr N1 becomes lower than Vn, as indicated by the equation (2). More precisely, with the PchTr P1 turned off, a series circuit of the resistor R3 and the load 12 is further connected in parallel with the resistor R4, and hence the gate voltage of the NchTr N1, divided from the power supply voltage, becomes smaller.

When the pushbutton switch SW is released, that is, opened, at a timing t4, the capacitor C is further charged to the voltage Vdc of the DC power supply 11 via resistors R1 and R2. Thus, when the pushbutton switch SW is again pressed at the timing t1, the NchTr N1 is again turned on.

FIG. 1 shows an electronic switch circuit for turning the load 12 on/off with the PchTr P1 driven by the NchTr N1. The same on/off function may, of course, be implemented by a configuration in which the load 12 is turned on or off by the NchTr N1 driven by the PchTr P1.

The electronic switch circuit, operating as described above, may be constituted by a MOSFET, performing a main switching function, a small MOSFET driving the first-stated MOSFET, a few resistors, a capacitor and a pushbutton switch. Moreover, with the conventional switch circuit, a toggle flipflop circuit operates normally only with a pulsed input. Thus, to obtain a desired pulse, the values of the resistor R or the capacitor C need to be set in consideration of the contact resistance of the pushbutton switch. With the electronic switch circuit of the present invention, it is scarcely necessary to take the contact resistance of the pushbutton switch SW into account, if only the capacitor C is charged/discharged sufficiently.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. An electronic switch circuit comprising:
a switch device;
a capacitive device alternately repeatedly charged and discharged responsive to a timing at which said switch device is opened/closed:
a field effect transistor of a first conductivity type controlled by a potential of said capacitive device so as to be alternately repeatedly rendered conductive and non-conductive; and
a field effect transistor of a second conductivity type for short-circuiting an electrical path between a power supply and a load responsive to a conductive state of said field effect transistor of the first conductivity type, said field effect transistor of the second conductivity type opening said electrical path responsive to a non-conductive state of said field effect transistor of the first conductivity type; said field effect transistor of the second conductivity type constituting a latch circuit together with said field effect transistor of the first conductivity type.

2. The electronic switch circuit according to claim 1 wherein
said field effect transistor of the first conductivity type has a gate, a source and a drain, said source being connectable to one end of said power supply and to one end of said load, said drain being connected to a gate of said field effect transistor of the second conductivity type;
said field effect transistor of the second conductivity type has said gate, a source and a drain, said source being connectable to the other end of said power supply, said drain being connectable to the other end of said load;
said capacitive device has one end connected to one end of said switch device and the other end connectable to said one end of said power supply; and
said switch device has said one end and the other end connected to said gate of said field effect transistor of the first conductivity type,
the electronic switch circuit further comprising:
a first resistor connected between said gate and said source of said field effect transistor of the second conductivity type;
a second resistor connected between said gate of said field effect transistor of the second conductivity type and said one end of said switch device;
a third resistor connected between said drain of said field effect transistor of the second conductivity type and said gate of said field effect transistor of the first conductivity type; and
a fourth resistor connected between said gate and said source of said field effect transistor of the first conductivity type.

3. The electronic switch circuit according to claim 2 wherein, with a resistance value R1 of said first resistor, a resistance value R2 of said second resistor, a resistance value R3 of said third resistor, a resistance value R4 of said fourth resistor, a gate cut-off voltage Vn of said field effect transistor of the first conductivity type, a gate cut-off voltage Vp of said field effect transistor of the second conductivity type, a gate voltage Vng of said field effect transistor of the first conductivity type for which said field effect transistor of the first conductivity type is turned on, and with a voltage Vdc of said DC power supply, the following relationships:
Vdc×R1/(R1+R2)<Vp
Vdc×R4/(R1+R2+R4)<Vn
Vdc×r0/(R3+r0)>Vng
are met, where
r0=R2×R4/(R2+R4).

4. The electronic switch circuit according to claim 1 wherein said switch device is a pushbutton switch.

5. The electronic switch circuit according to claim 2 wherein said switch device is a pushbutton switch.
